(19) United States
(12) Patent Application Publication
(10) Pub. No.: US 2024/0055402 A1
(43) Pub. Date: Feb. 15, 2024

(54) ELECTRONIC PACKAGE AND MANUFACTURING METHOD THEREOF

(71) Applicant: SILICONWARE PRECISION INDUSTRIES CO., LTD., Taichung (TW)

(72) Inventors: Lung-Yuan WANG, Taichung (TW); Feng KAO, Taichung (TW); Chiu-Ling CHEN, Taichung (TW); Hung-Kai WANG, Taichung (TW)

(73) Assignee: SILICONWARE PRECISION INDUSTRIES CO., LTD., Taichung (TW)

(21) Appl. No.: 18/063,399

(22) Filed: Dec. 8, 2022

(30) Foreign Application Priority Data
Aug. 9, 2022 (TW) 111129904

(51) Int. Cl. H01L 25/065; H01L 21/48; H01L 23/31; H01L 23/498; H01L 23/00

(52) U.S. Cl. CPC H01L 25/0657; H01L 21/486; H01L 23/3128; H01L 23/49816; H01L 23/49827; H01L 24/73; H01L 24/81; H01L 2224/81815; H01L 2224/73204

(57) ABSTRACT

An electronic package is provided, in which a stacking component and a plurality of conductive pillars are embedded in a packaging layer, and a routing structure is formed on the packaging layer, where the stacking component is formed by stacking a first electronic module and a second electronic module on each other, and a plurality of first conductive vias and a plurality of second conductive vias are served as the electrical connection paths between the first electronic module and the second electronic module, such that the transmission distance of electrical signals between a first electronic element in the first electronic module and a second electronic element in the second electronic module can be reduced.

### BACKGROUND

### 1. Technical Field

The present disclosure relates to a semiconductor device, and more particularly, to an electronic package with electronic element stacking structure and manufacturing method thereof.

### 2. Description of Related Art

Electronic products are gradually moving towards a trend of multi-function and high performance along with the vigorous development in the electronic industry. Meanwhile, technologies currently applied in the field of chip packaging include flip-chip packaging modules such as chip scale package (CSP), direct chip attached (DCA), or multi-chip module (MCM).

FIG. 1 is a schematic cross-sectional view of a conventional semiconductor package 1. As shown in FIG. 1, the semiconductor package 1 has a plurality of semiconductor chips 1a, 1b and a plurality of conductive pillars 13 embedded in a packaging layer 11, and a first routing structure 10 electrically connected to the plurality of conductive pillars 13 is formed on an upper side of the packaging layer 11, and a second routing structure 12 electrically connected to the plurality of semiconductor chips 1a, 1b and the plurality of conductive pillars 13 is formed on a lower side of the packaging layer 11.

However, in the conventional semiconductor package 1, the plurality of semiconductor chips 1a, 1b are integrated into a single stacking component in a side by side manner, so that the transmission distance of the lateral (e.g., arrow direction X shown in FIG. 1) electrical signals between the two semiconductor chips 1a, 1b is too long, resulting in poor electrical performance, such that the conventional semiconductor package 1 fails to meet the performance requirement of the end product.

Therefore, how to overcome the aforementioned drawbacks of the prior art has become an urgent issue to be addressed at present.

### SUMMARY

In view of the various shortcomings of the prior art, the present disclosure provides an electronic package, which comprises: a packaging layer; a stacking component embedded in the packaging layer and comprising a first electronic module and a second electronic module stacked on the first electronic module, wherein the first electronic module comprises a first encapsulation layer, a first electronic element embedded in the first encapsulation layer, a plurality of first conductive vias embedded in the first encapsulation layer, and at least one first circuit structure disposed on the first encapsulation layer and electrically connected to the first electronic element and the plurality of first conductive vias, wherein the second electronic module comprises a second encapsulation layer, a second electronic element embedded in the second encapsulation layer, a plurality of second conductive vias embedded in the second encapsulation layer, and at least one second circuit structure disposed on the second encapsulation layer and electrically connected to the second electronic element and the plurality of second conductive vias, wherein the plurality of first conductive vias are electrically connected to the plurality of second conductive vias; a plurality of conductive pillars embedded in the packaging layer; and a routing structure formed on the packaging layer and electrically connected to the plurality of conductive pillars and the stacking component.

The present disclosure further provides a method of manufacturing an electronic package, the method comprises: providing a first electronic module and a second electronic module, wherein the first electronic module comprises a first encapsulation layer, a first electronic element embedded in the first encapsulation layer, a plurality of first conductive vias embedded in the first encapsulation layer, and at least one first circuit structure disposed on the first encapsulation layer and electrically connected to the first electronic element and the plurality of first conductive vias, wherein the second electronic module comprises a second encapsulation layer, a second electronic element embedded in the second encapsulation layer, a plurality of second conductive vias embedded in the second encapsulation layer, and at least one second circuit structure disposed on the second encapsulation layer and electrically connected to the second electronic element and the plurality of second conductive vias; stacking the first electronic module and the second electronic module on each other to form a stacking component, wherein the plurality of first conductive vias are electrically connected to the plurality of second conductive vias; disposing the stacking component on a carrier, wherein the carrier has a plurality of conductive pillars formed thereon, wherein the stacking component is disposed onto the carrier with the first electronic module and/or the second electronic module; forming a packaging layer on the carrier, wherein the packaging layer covers the plurality of conductive pillars and the stacking component; forming a routing structure on the packaging layer, wherein the routing structure is electrically connected to the plurality of conductive pillars and the stacking component; and removing the carrier.

In the aforementioned manufacturing method, the present disclosure further comprises forming another routing structure on the carrier, wherein the stacking component is disposed onto the another routing structure.

In the aforementioned manufacturing method, the carrier and the plurality of conductive pillars are an integrally formed metal member.

In the aforementioned electronic package and method, a configuration of the first electronic module and a configuration of the second electronic module are the same.

In the aforementioned electronic package and method, materials of at least two of the packaging layer, the first encapsulation layer and the second encapsulation layer are the same.

In the aforementioned electronic package and method, materials of at least two of the packaging layer, the first encapsulation layer and the second encapsulation layer are different.

In the aforementioned electronic package and method, the at least one first circuit structure is a plurality of first circuit structures respectively disposed on opposing sides of the first encapsulation layer, and wherein the at least one second circuit structure is a plurality of second circuit structures respectively disposed on opposing sides of the second encapsulation layer. For instance, one of the plurality of first circuit structures has a plurality of first electrical contact pads, and the other one of the plurality of first circuit structures has a plurality of first conductive bumps, wherein one of the plurality of second circuit structures has a plurality of second conductive bumps, and the other one of the plurality of second circuit structures has a plurality of second electrical contact pads, wherein the second electronic module is disposed onto the plurality of first electrical contact pads of the first electronic module with the plurality of second conductive bumps via a solder material. Furthermore, the present disclosure further comprises covering, by a bonding material, the plurality of second conductive bumps, the solder material and the first electrical contact pads. Alternatively, the present disclosure further comprises covering, by a packaging material, the plurality of second conductive bumps, the solder material, the first electrical contact pads and the second electronic module. Even, the present disclosure further comprises firstly covering the plurality of second conductive bumps, the solder material and the first electrical contact pads via a bonding material, and then covering the bonding material and the second electronic module via a packaging material.

In the aforementioned electronic package and method, the first circuit structure or the second circuit structure has a plurality of conductive bumps electrically connected to the routing structure.

In the aforementioned electronic package and method, the first circuit structure or the second circuit structure has a plurality of electrical contact pads electrically connected to the routing structure.

As can be understood from the above, in the electronic package and manufacturing method thereof of the present disclosure, the first electronic module and the second electronic module are stacked on each other, and the first conductive vias and the second conductive vias are served as the electrical connection paths between the first electronic module and the second electronic module, such that the transmission distance of the electrical signals between the first electronic element and the second electronic element is reduced. Hence, compared to the prior art, the electronic package of the present disclosure can improve electrical performance via fast/short and low-loss vertical circuit conduction paths, thereby meeting the performance requirements of the end product.

In addition, the material of the packaging layer can be selected according to the degree of warpage of the stacking component, so that the warpage pattern of the packaging layer can be mutually eliminated with the stacking component, so as to improve the yield of the electronic package being subsequently disposed onto the electronic device.

### BRIEF DESCRIPTION OF THE DRAWINGS

FIG. 1 is a schematic cross-sectional view of a conventional semiconductor package.

FIG. 2A, FIG. 2B-1, FIG. 2C, FIG. 2D, FIG. 2E, FIG. 2F and FIG. 2G are schematic cross-sectional views illustrating a manufacturing method of an electronic package according to a first embodiment of the present disclosure.

FIG. 2B-2 and FIG. 2B-3 are schematic cross-sectional views showing different aspects of FIG. 2B-1.

FIG. 3A and FIG. 3B are schematic cross-sectional views showing different aspects of FIG. 2G.

FIG. 4A to FIG. 4D are schematic cross-sectional views illustrating a manufacturing method of an electronic package according to a second embodiment of the present disclosure.

### DETAILED DESCRIPTIONS

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “one,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

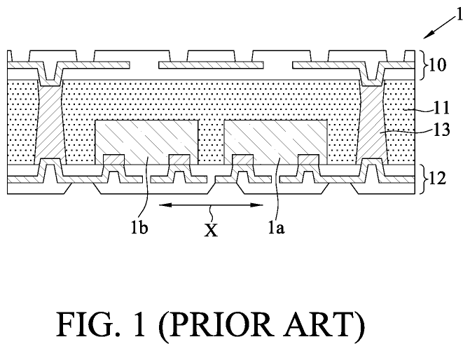

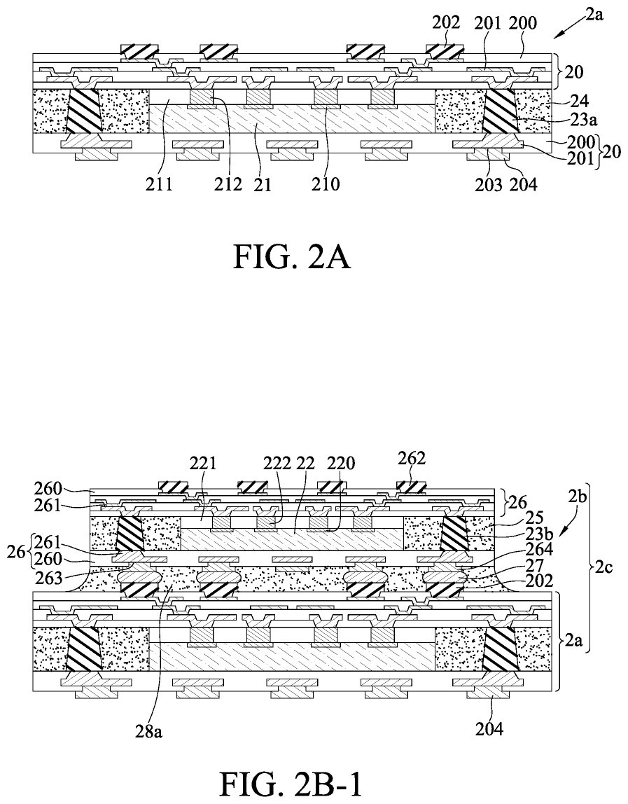

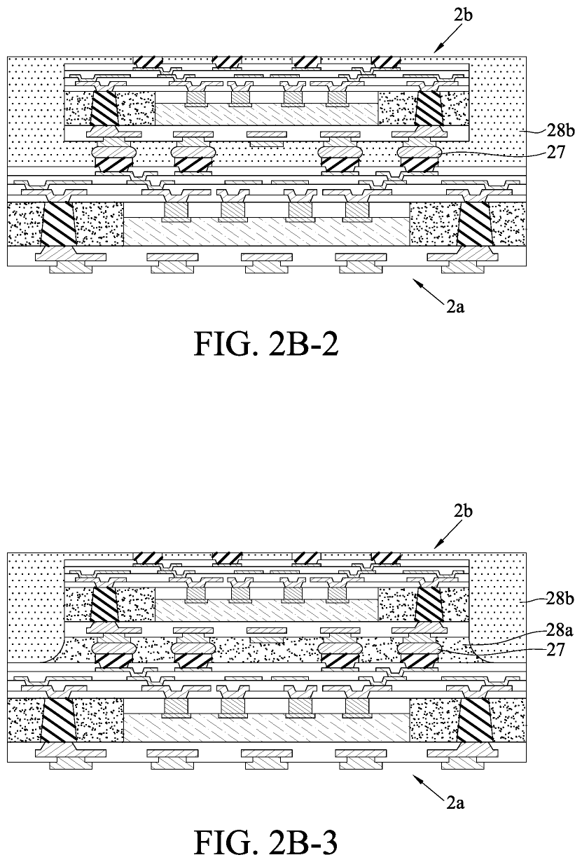

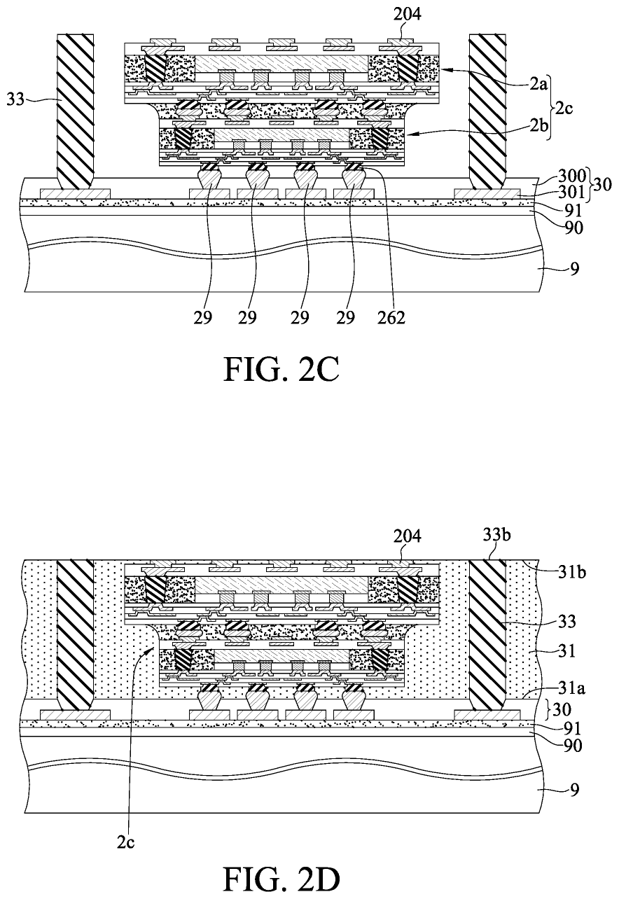

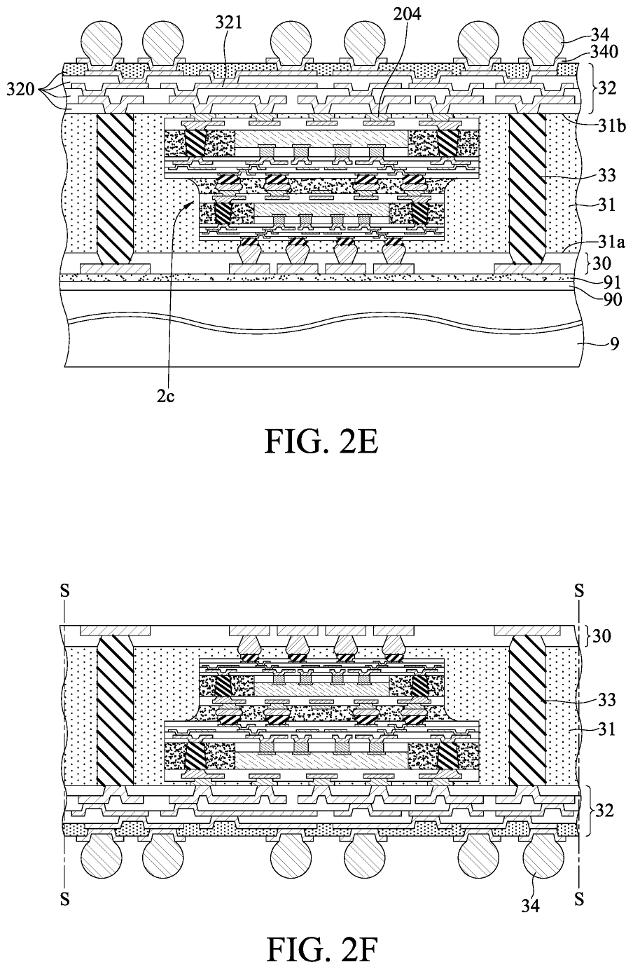

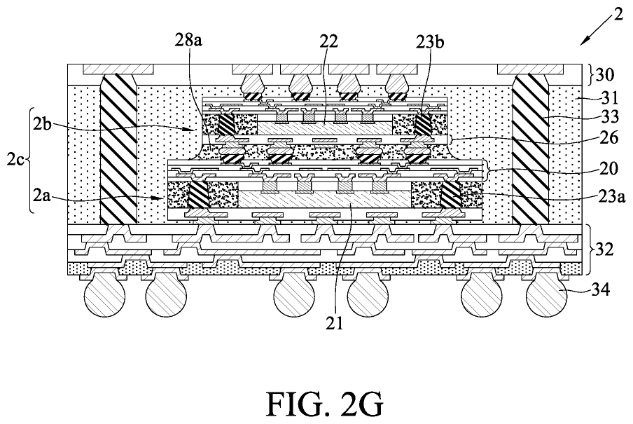

FIG. 2A, FIG. 2B-1, FIG. 2C, FIG. 2D, FIG. 2E, FIG. 2F and FIG. 2G are schematic cross-sectional views illustrating a manufacturing method of an electronic package 2 according to a first embodiment of the present disclosure.

As shown in FIG. 2A, a first electronic module 2a is provided, which comprises: a first encapsulation layer 24, at least one first electronic element 21 embedded in the first encapsulation layer 24, a plurality of first conductive vias 23a embedded in the first encapsulation layer 24, and two first circuit structures 20 respectively disposed on opposing sides of the first encapsulation layer 24.

The first encapsulation layer 24 is made from an insulating material, such as polyimide (PI), dry film, epoxy resin, molding compound, or other packaging materials.

The first electronic element 21 is an active element, a passive element, or a combination of the active element and the passive element, wherein the active element is such as a semiconductor chip, and the passive element is such as a resistor, a capacitor, or an inductor. In an embodiment, the first electronic element 21 is a semiconductor chip having a plurality of first electrode pads 210 so that the first electronic element 21 is electrically connected to the first circuit structure 20 via a plurality of first conductors 212 such as copper bumps, wherein the first conductors 212 are covered by a first insulating film 211, and the first electronic element 21 is free from having a through silicon via (TSV) structure.

The first conductive vias 23a penetrate through the first encapsulation layer 24 to electrically connect to the two first circuit structures 20, and the first conductive vias 23a can be metal pillars such as copper pillars, solder bumps, or other appropriate structures capable of vertically and electrically connecting signals, and the present disclosure is not limited to as such.

The first circuit structure 20 is electrically connected to the plurality of first conductive vias 23a and the plurality of first electrode pads 210, and the first circuit structure 20 comprises at least one first dielectric layer 200 and at least one first circuit layer 201 bonded with the first dielectric layer 200, such that the outermost first circuit layer 201 is exposed from the first dielectric layer 200 and served as first electrical contact pads 202, 203, wherein the first electrical contact pads 202 of one of the two first circuit structures 20 are of a micro-pad (μ-pad) specification, and first conductive bumps 204 of a micro-bump (μ-bump) specification are formed on the first electrical contact pads 203 of the other of the two first circuit structures 20.

In an embodiment, the first circuit layer 201 is formed via a redistribution layer (RDL) manufacturing method, and the material for forming the first circuit layer 201 is copper. In an embodiment, the material for forming the first dielectric layer 200 is a dielectric material such as polybenzoxazole (PBO), polyimide (PI), prepreg (PP), or the like. It should be understood that the first circuit structure 20 may also comprise only a single dielectric layer and a single circuit layer.

As shown in FIG. 2B-1, a second electronic module 2b is stacked on the first electronic module 2a to form a stacking component 2c, wherein the configuration/structure of the first electronic module 2a and the configuration/structure of the second electronic module 2b can be the same or different.

In an embodiment, the configuration of the first electronic module 2a is the same as the configuration of the second electronic module 2b, but the size (e.g., volume or width) of the first electronic module 2a is larger than the size of the second electronic module 2b, wherein the second electronic module 2b comprises: a second encapsulation layer 25, at least one second electronic element 22 embedded in the second encapsulation layer 25, a plurality of second conductive vias 23b embedded in the second encapsulation layer 25, and two second circuit structures 26 respectively disposed on opposing sides of the second encapsulation layer 25.

The second encapsulation layer 25 is made from an insulating material, such as polyimide (PI), dry film, epoxy resin, molding compound, or other packaging materials.

The second electronic element 22 is an active element, a passive element, or a combination of the active element and the passive element, wherein the active element is such as a semiconductor chip, and the passive element is such as a resistor, a capacitor, or an inductor. In an embodiment, the second electronic element 22 is a semiconductor chip having a plurality of second electrode pads 220 so that the second electronic element 22 is electrically connected to the second circuit structure 26 via a plurality of second conductors 222 such as copper bumps, wherein the second conductors 222 are covered by a second insulating film 221, and the second electronic element 22 is free from having a through silicon via (TSV) structure.

The second conductive vias 23b penetrate through the second encapsulation layer 25 to electrically connect to the two second circuit structures 26, and the second conductive vias 23b can be metal pillars such as copper pillars, solder bumps, or other appropriate structures capable of vertically and electrically connecting signals, and the present disclosure is not limited to as such.

The second circuit structure 26 is electrically connected to the plurality of second conductive vias 23b and the plurality of second electrode pads 220, and the second circuit structure 26 comprises at least one second dielectric layer 260 and at least one second circuit layer 261 bonded with the second dielectric layer 260, such that the outermost second circuit layer 261 is exposed from the second dielectric layer 260 and served as second electrical contact pads 262, 263, wherein the second electrical contact pads 262 of one of the two second circuit structures 26 are of a micro-pad (μ-pad) specification, and second conductive bumps 264 of a micro-bump (μ-bump) specification are formed on the second electrical contact pads 263 of the other of the two second circuit structures 26.

In an embodiment, the second circuit layer 261 is formed via a redistribution layer (RDL) manufacturing method, and the material for forming the second circuit layer 261 is copper. In an embodiment, the material for forming the second dielectric layer 260 is a dielectric material such as polybenzoxazole (PBO), polyimide (PI), prepreg (PP), or the like. It should be understood that the second circuit structure 26 may also comprise only a single dielectric layer and a single circuit layer.

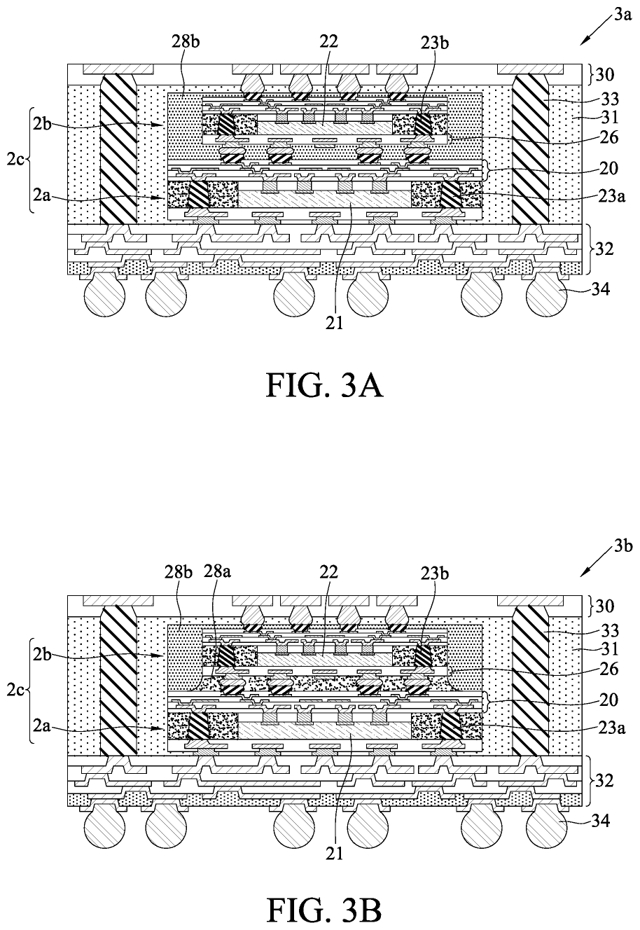

Moreover, the second electronic module 2b is bonded with the first electrical contact pads 202 of the first electronic module 2a with the second conductive bumps 264 thereof via a solder material 27, and a bonding material/layer 28a (as shown in FIG. 2B-1) of an underfill or a non-conductive film (NCF) can be used to cover the second conductive bumps 264, the solder material 27 and the first electrical contact pads 202, so that the first electronic module 2a and the second electronic module 2b can be packaged and fixed to each other. Alternatively, as shown in FIG. 2B-2, a packaging material 28b can be used to cover the second conductive bumps 264, the solder material 27, the first electrical contact pads 202 and the second electronic module 2b, so that the second electronic module 2b can be packaged and fixed on the first electronic module 2a. Even, as shown in FIG. 2B-3, the bonding material 28a can be used together with the packaging material 28b; for instance, the bonding material 28a is used to cover the second conductive bumps 264, the solder material 27 and the first electrical contact pads 202 first, and then the packaging material 28b is used to cover the bonding material 28a and the second electronic module 2b.

In addition, the packaging material 28b is made of a molding compound or other materials/compounds, and the present disclosure is not limited to as such. It should be understood that the material of the first encapsulation layer 24, the material of the second encapsulation layer 25 and the material of the packaging material 28b can be the same or different.

Therefore, the bonding material 28a and/or the packaging material 28b are designed (e.g., through matching, material, and other choices) to facilitate the adjustment of the degree of warpage of the stacking component 2c, and the stacking component 2c is formed into a stacked packaging structure with a substantially square appearance through the protection of the packaging material 28b, so as to be beneficial to improve stability and reliability of the subsequent processes.

As shown in FIG. 2C, a first routing structure 30 is formed and disposed on a carrier 9, then a plurality of conductive pillars 33 are formed on the first routing structure 30, and the stacking component 2c is disposed on the first routing structure 30.

In an embodiment, the carrier 9 is such as a carrier plate made of semiconductor material (e.g., silicon or glass), and a release layer 90 and a bonding layer 91 are formed sequentially on the carrier 9 by for example coating, so that the first routing structure 30 is disposed on the bonding layer 91.

Moreover, the first routing structure 30 comprises at least one first insulating layer 300 and at least one first redistribution layer (RDL) 301 disposed on the first insulating layer 300. For instance, the material for forming the first redistribution layer 301 is copper, and the material for forming the first insulating layer 300 is a dielectric material such as polybenzoxazole (PBO), polyimide (PI), prepreg (PP), or the like.

Furthermore, the conductive pillars 33 are disposed on the first redistribution layer 301 to electrically connect the first redistribution layer 301, and the material for forming the conductive pillars 33 is a metal material such as copper or a solder material. For instance, the conductive pillars 33 are formed by electroplating on the first redistribution layer 301 via exposure and development.

In addition, the stacking component 2c is adopted as the aspect shown in FIG. 2B-1, where the second electrical contact pads 262 of the second electronic module 2b are disposed onto the first redistribution layer 301 via a solder material 29, and the first conductive bumps 204 of the first electronic module 2a are exposed.

As shown in FIG. 2D, a packaging layer 31 is formed on the first routing structure 30, such that the packaging layer 31 covers the stacking component 2c and the conductive pillars 33, and the conductive pillars 33 and the first conductive bumps 204 are exposed from the packaging layer 31.

In an embodiment, the packaging layer 31 has a first surface 31a bonding to the first routing structure 30 and a second surface 31b opposing the first surface 31a, and the packaging layer 31 is made from an insulating material such as polyimide (PI), dry film, epoxy resin, molding compound, or other packaging materials. For instance, the packaging layer 31 can be formed on the first insulating layer 300 via liquid compound, injection, lamination, or compression molding. It should be understood that the material of the packaging layer 31, the material of the first encapsulation layer 24, the material of the second encapsulation layer 25 and the material of the packaging material 28b can be the same or different.

In addition, the second surface 31b of the packaging layer 31 can be flush with end surfaces 33b of the plurality of conductive pillars 33 and end surfaces of the plurality of first conductive bumps 204 via a leveling process, such that the end surfaces 33b of the plurality of conductive pillars 33 and the end surfaces of the plurality of first conductive bumps 204 are exposed from the second surface 31b of the packaging layer 31. For instance, the leveling process is used to remove a portion of the material of each of the conductive pillars 33 and a portion of the material of the packaging layer 31 by grinding.

As shown in FIG. 2E, a second routing structure 32 is formed on the second surface 31b of the packaging layer 31, and the second routing structure 32 is electrically connected to the conductive pillars 33 and the plurality of first conductive bumps 204 of the stacking component 2c.

In an embodiment, the second routing structure 32 comprises a plurality of second insulating layers 320 and a plurality of second redistribution layers 321 disposed on the second insulating layers 320, and the outermost second insulating layer 320 can be used as a solder mask layer, such that the outermost second redistribution layer 321 is exposed from the solder mask layer. Alternatively, the second routing structure 32 may also comprise only a single second insulating layer 320 and a single second redistribution layer 321.

Moreover, the material for forming the second redistribution layer 321 is copper, and the material for forming the second insulating layer 320 is a dielectric material such as polybenzoxazole (PBO), polyimide (PI), prepreg (PP), or the like.

Furthermore, a plurality of conductive elements 34 such as solder balls are formed on the outermost second redistribution layer 321, so that an electronic device (not shown) such as a packaging structure or other structure (e.g., another package or chip) can be connected subsequently. For instance, an under bump metallurgy (UBM) layer 340 can be formed on the outermost second redistribution layer 321 so as to facilitate the bonding of the conductive elements 34.

As shown in FIG. 2F, the structure shown in FIG. 2E is flipped, then the carrier 9 and the release layer 90 and the bonding layer 91 thereon are removed to expose the first routing structure 30.

As shown in FIG. 2G, a singulation process is performed along a cutting path S shown in FIG. 2F to obtain the electronic package 2 of the present disclosure.

In an embodiment, if the stacking component 2c is adopted as the aspect shown in FIG. 2B-2 or FIG. 2B-3, an electronic package 3a shown in FIG. 3A and an electronic package 3b shown in FIG. 3B would be obtained.

Therefore, in the manufacturing method of the present disclosure, the first electronic module 2a composed of the first electronic element 21 and the second electronic module 2b composed of the second electronic element 22 are stacked on each other with respect to the vertical direction of the first circuit structure 20, and the first conductive vias 23a and the second conductive vias 23b are served as the electrical connection paths between the first electronic module 2a and the second electronic module 2b, such that the transmission distance of the electrical signals between the first electronic element 21 and the second electronic element 22 is reduced. Hence, compared to the prior art, the electronic package 2, 3a, 3b of the present disclosure can improve electrical performance via fast/short and low-loss vertical circuit conduction paths, thereby meeting the performance requirements of the end product.

In addition, the material of the packaging layer 31 can be selected according to the degree of warpage of the stacking component 2c, so that the warpage pattern of the packaging layer 31 after removing the carrier 9 and the release layer 90 and the bonding layer 91 thereon can be mutually eliminated with the stacking component 2c, so as to improve the yield of the electronic package 2, 3a, 3b being subsequently disposed onto the electronic device. For instance, the material of the first encapsulation layer 24, the material of the second encapsulation layer 25, the material of the packaging material 28b (such as the aspect shown in FIG. 2B-2 or FIG. 2B-3) and the material of the packaging layer 31 can be adjusted, so that the degree of freedom of warpage adjustment can be increased.

Moreover, the first circuit structures 20 are disposed on opposing sides of the first encapsulation layer 24 and/or the second circuit structures 26 are disposed on opposing sides of the second encapsulation layer 25, so that the flexibility for structural variations can be increased, such that the active surfaces (surfaces with the first and second electrode pads 210, 220) of the first and second electronic elements 21, 22 in the stacked first and second electronic modules 2a, 2b can be arranged/configured according to requirements, such as face to face, back to back, or face to back, so as to vary with electrical requirements.

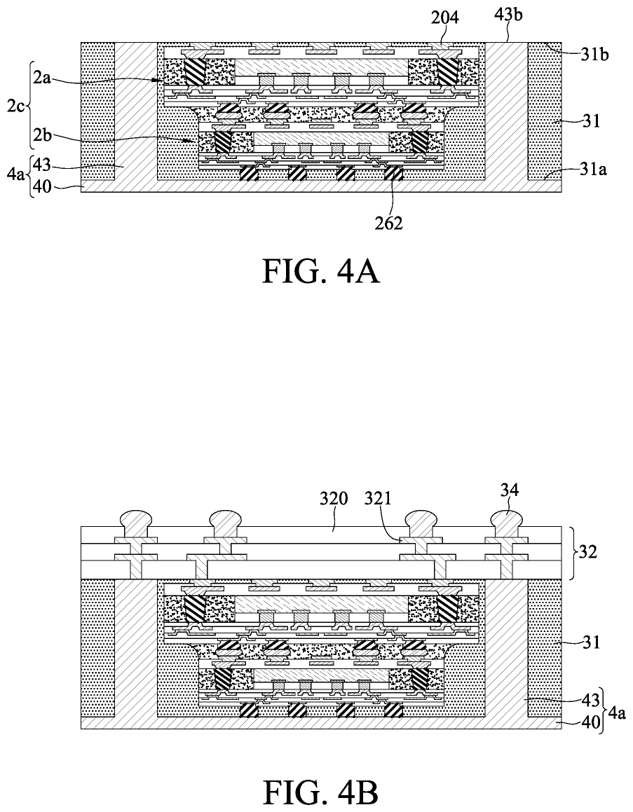

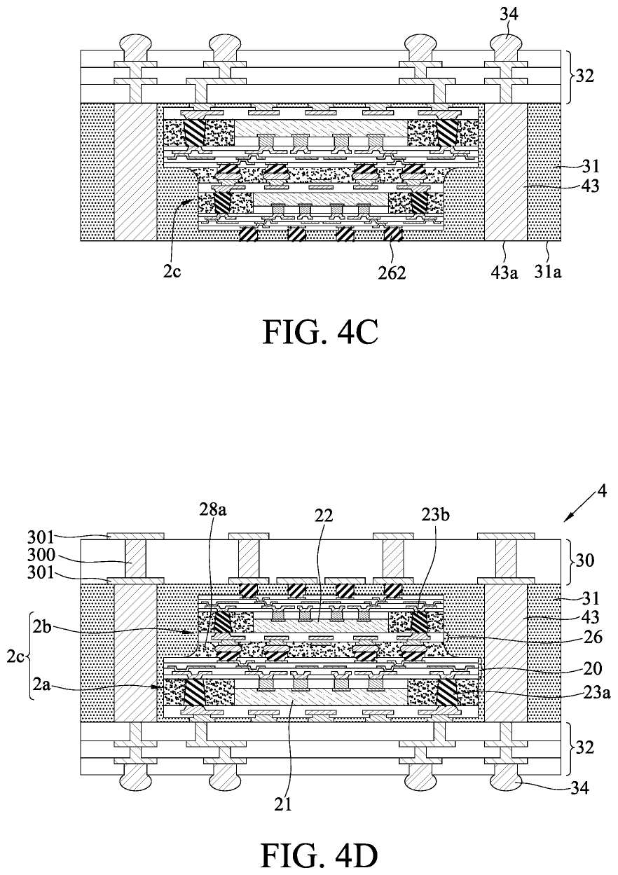

FIG. 4A to FIG. 4D are schematic cross-sectional views illustrating a manufacturing method of an electronic package 4 according to a second embodiment of the present disclosure. The difference between the second embodiment and the first embodiment lies in the design of the carrier plate, so the same technical features will not be repeated below.

As shown in FIG. 4A, following the manufacturing process shown in FIG. 2B-1, a metal member 4a is provided and comprises a carrier 40 and a plurality of conductive pillars 43 disposed on the carrier 40. Then, the stacking component 2c is disposed onto the carrier 40 with the second electronic module 2b thereof, and then the packaging layer 31 is formed on the carrier 40, such that the packaging layer 31 covers the stacking component 2c and the conductive pillars 43.

In an embodiment, the carrier 40 and the conductive pillars 43 are integrally formed. For instance, the material on a metal plate is removed by etching, laser, or other means to form the metal member 4a.

In addition, the packaging layer 31 is bonded with the carrier 40 with the first surface 31a thereof, and the second surface 31b of the packaging layer 31 can be flush with end surfaces 43b of the plurality of conductive pillars 43 and end surfaces of the plurality of first conductive bumps 204 of the first electronic module 2a via a leveling process, such that the end surfaces 43b of the plurality of conductive pillars 43 and the end surfaces of the plurality of first conductive bumps 204 are exposed from the second surface 31b of the packaging layer 31. For instance, the leveling process is used to remove a portion of the material of each of the conductive pillars 33 and a portion of the material of the packaging layer 31 by grinding.

As shown in FIG. 4B, the second routing structure 32 is formed on the second surface 31b of the packaging layer 31, and the plurality of conductive elements 34 such as solder balls are formed on the outermost second redistribution layer 321.

As shown in FIG. 4C, the carrier 40 is removed, such that the plurality of conductive pillars 43 and the plurality of second electrical contact pads 262 are exposed from the first surface 31a of the packaging layer 31.

In an embodiment, the carrier 40 is removed by grinding. For instance, the first surface 31a of the packaging layer 31 is flush with end surfaces 43a of the plurality of conductive pillars 43 and end surfaces of the second electrical contact pads 262 via a leveling process, such that the conductive pillars 43 and the second electrical contact pads 262 are exposed from the first surface 31a of the packaging layer 31.

As shown in FIG. 4D, the structure shown in FIG. 4C is flipped, then the first routing structure 30 is formed on the first surface 31a of the packaging layer 31, so that the first routing structure 30 is electrically connected to the plurality of conductive pillars 43 and the plurality of second electrical contact pads 262, thereby obtaining the electronic package 4 of the present disclosure.

In an embodiment, the end surfaces 43a of the conductive pillars 43 can also be served as external contacts, so that the first routing structure 30 does not need to be fabricated.

Therefore, in the manufacturing method of the present disclosure, the first electronic module 2a composed of the first electronic element 21 and the second electronic module 2b composed of the second electronic element 22 are stacked on each other with respect to the vertical direction of the carrier 40, and the first conductive vias 23a and the second conductive vias 23b are served as the electrical connection paths between the first electronic module 2a and the second electronic module 2b, such that the transmission distance of the electrical signals between the first electronic element 21 and the second electronic element 22 is reduced. Hence, compared to the prior art, the electronic package 4 of the present disclosure can improve electrical performance via fast/short and low-loss vertical circuit conduction paths, thereby meeting the performance requirements of the end product.

In addition, the material of the packaging layer 31 can be selected according to the degree of warpage of the stacking component 2c, so that the warpage pattern of the packaging layer 31 after removing the carrier 40 can be mutually eliminated with the stacking component 2c, so as to improve the yield of the electronic package 4 being subsequently disposed onto the electronic device.

It should be understood that, in the first embodiment and the second embodiment of the aforementioned manufacturing methods of the present disclosure, the stacking component 2c can also be disposed onto the carrier 9, 40 with the first electronic module 2a thereof.

The present disclosure also provides an electronic package 2, 3a, 3b, 4, comprising: a packaging layer 31, a stacking component 2c, a plurality of conductive pillars 33, 43, and a first routing structure 30 and a second routing structure 32.

The stacking component 2c is embedded in the packaging layer 31, and the stacking component 2c comprises a first electronic module 2a and a second electronic module 2b stacked on the first electronic module 2a.

The first electronic module 2a comprises: a first encapsulation layer 24; at least one first electronic element 21 embedded in the first encapsulation layer 24; a plurality of first conductive vias 23a embedded in the first encapsulation layer 24; and at least one first circuit structure 20 disposed on the first encapsulation layer 24 and electrically connected to the first electronic element 21 and the plurality of first conductive vias 23a.

The second electronic module 2b comprises: a second encapsulation layer 25; at least one second electronic element 22 embedded in the second encapsulation layer 25; a plurality of second conductive vias 23b embedded in the second encapsulation layer 25; and at least one second circuit structure 26 disposed on the second encapsulation layer 25 and electrically connected to the second electronic element 22 and the plurality of second conductive vias 23b.

The conductive pillars 33, 43 are embedded in the packaging layer 31.

The first routing structure 30 and the second routing structure 32 are formed on the packaging layer 31 and electrically connected to the plurality of conductive pillars 33, 43 and the stacking component 2c.

In an embodiment, a configuration of the first electronic module 2a and a configuration of the second electronic module 2b are the same.

In an embodiment, materials of at least two of the packaging layer 31, the first encapsulation layer 24 and the second encapsulation layer 25 are the same.

In an embodiment, the materials of at least two of the packaging layer 31, the first encapsulation layer 24 and the second encapsulation layer 25 are different.

In an embodiment, the at least one first circuit structure 20 is a plurality of first circuit structures 20 respectively disposed on opposing sides of the first encapsulation layer 24, and the at least one second circuit structure 26 is a plurality of second circuit structures 26 respectively disposed on opposing sides of the second encapsulation layer 25. For instance, one of the plurality of first circuit structures 20 has a plurality of first electrical contact pads 202, and the other one of the plurality of first circuit structures 20 has a plurality of first conductive bumps 204, and one of the plurality of second circuit structures 26 has a plurality of second conductive bumps 264, and the other one of the plurality of second circuit structures 26 has a plurality of second electrical contact pads 262, such that the second electronic module 2b is disposed onto the plurality of first electrical contact pads 202 of the first electronic module 2a with the plurality of second conductive bumps 264 via a solder material 27.

Furthermore, in the electronic package 2, 4, the stacking component 2c further comprises a bonding material 28a covering the plurality of second conductive bumps 264, the solder material 27 and the first electrical contact pads 202.

Alternatively, in the electronic package 3a, the stacking component 2c further comprises a packaging material 28b covering the plurality of second conductive bumps 264, the solder material 27 and the first electrical contact pads 202.

Even, in the electronic package 3b, the stacking component 2c further comprises the bonding material 28a covering the plurality of second conductive bumps 264, the solder material 27 and the first electrical contact pads 202, and the packaging material 28b covering the bonding material 28a and the second electronic module 2b.

In an embodiment, the first circuit structure 20 (or the second circuit structure 26) has the plurality of first conductive bumps 204 electrically connected to the second routing structure 32.

In an embodiment, the second circuit structure 26 (or the first circuit structure 20) has the plurality of second electrical contact pads 262 electrically connected to the first routing structure 30.

To sum up, in the electronic package and manufacturing method thereof of the present disclosure, the first electronic module composed of the first electronic element and the second electronic module composed of the second electronic element are stacked on each other in the vertical direction, and the first conductive vias and the second conductive vias are served as the electrical connection paths between the first electronic module and the second electronic module, such that the transmission distance of the electrical signals between the first electronic element and the second electronic element is reduced. Hence, the electronic package of the present disclosure can improve electrical performance via fast/short and low-loss vertical circuit conduction paths, thereby meeting the performance requirements of the end product.

In addition, the material of the packaging layer can be selected according to the degree of warpage of the stacking component, so that the warpage pattern of the packaging layer can be mutually eliminated with the stacking component, so as to improve the yield of the electronic package being subsequently disposed onto the electronic device.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a packaging layer;
a stacking component embedded in the packaging layer and comprising a first electronic module and a second electronic module stacked on the first electronic module, wherein the first electronic module comprises a first encapsulation layer, a first electronic element embedded in the first encapsulation layer, a plurality of first conductive vias embedded in the first encapsulation layer, and at least one first circuit structure disposed on the first encapsulation layer and electrically connected to the first electronic element and the plurality of first conductive vias, wherein the second electronic module comprises a second encapsulation layer, a second electronic element embedded in the second encapsulation layer, a plurality of second conductive vias embedded in the second encapsulation layer, and at least one second circuit structure disposed on the second encapsulation layer and electrically connected to the second electronic element and the plurality of second conductive vias, wherein the plurality of first conductive vias are electrically connected to the plurality of second conductive vias;
a plurality of conductive pillars embedded in the packaging layer; and
a routing structure formed on the packaging layer and electrically connected to the plurality of conductive pillars and the stacking component.

2. The electronic package of claim 1, wherein a configuration of the first electronic module and a configuration of the second electronic module are the same.

3. The electronic package of claim 1, wherein materials of at least two of the packaging layer, the first encapsulation layer and the second encapsulation layer are the same.

4. The electronic package of claim 1, wherein materials of at least two of the packaging layer, the first encapsulation layer and the second encapsulation layer are different.

5. The electronic package of claim 1, wherein the at least one first circuit structure is a plurality of first circuit structures respectively disposed on opposing sides of the first encapsulation layer, and wherein the at least one second circuit structure is a plurality of second circuit structures respectively disposed on opposing sides of the second encapsulation layer.

6. The electronic package of claim 5, wherein one of the plurality of first circuit structures has a plurality of first electrical contact pads, and the other one of the plurality of first circuit structures has a plurality of first conductive bumps, wherein one of the plurality of second circuit structures has a plurality of second conductive bumps, and the other one of the plurality of second circuit structures has a plurality of second electrical contact pads, wherein the second electronic module is disposed onto the plurality of first electrical contact pads of the first electronic module with the plurality of second conductive bumps via a solder material.

7. The electronic package of claim 6, wherein the stacking component further comprises a bonding material covering the plurality of second conductive bumps, the solder material and the first electrical contact pads.

8. The electronic package of claim 6, wherein the stacking component further comprises a packaging material covering the plurality of second conductive bumps, the solder material, the first electrical contact pads and the second electronic module.

9. The electronic package of claim 6, wherein the stacking component further comprises a bonding material covering the plurality of second conductive bumps, the solder material and the first electrical contact pads, and a packaging material covering the bonding material and the second electronic module.

10. The electronic package of claim 1, wherein the first circuit structure or the second circuit structure has a plurality of conductive bumps electrically connected to the routing structure.

11. The electronic package of claim 1, wherein the first circuit structure or the second circuit structure has a plurality of electrical contact pads electrically connected to the routing structure.

12. A method of manufacturing an electronic package, comprising:
providing a first electronic module and a second electronic module, wherein the first electronic module comprises a first encapsulation layer, a first electronic element embedded in the first encapsulation layer, a plurality of first conductive vias embedded in the first encapsulation layer, and at least one first circuit structure disposed on the first encapsulation layer and electrically connected to the first electronic element and the plurality of first conductive vias, wherein the second electronic module comprises a second encapsulation layer, a second electronic element embedded in the second encapsulation layer, a plurality of second conductive vias embedded in the second encapsulation layer, and at least one second circuit structure disposed on the second encapsulation layer and electrically connected to the second electronic element and the plurality of second conductive vias;
stacking the first electronic module and the second electronic module on each other to form a stacking component, wherein the plurality of first conductive vias are electrically connected to the plurality of second conductive vias;
disposing the stacking component on a carrier, wherein the carrier has a plurality of conductive pillars formed thereon, wherein the stacking component is disposed onto the carrier with the first electronic module and/or the second electronic module;
forming a packaging layer on the carrier, wherein the packaging layer covers the plurality of conductive pillars and the stacking component;
forming a routing structure on the packaging layer, wherein the routing structure is electrically connected to the plurality of conductive pillars and the stacking component; and
removing the carrier.

13. The method of claim 12, wherein a configuration of the first electronic module and a configuration of the second electronic module are the same.

14. The method of claim 12, wherein materials of at least two of the packaging layer, the first encapsulation layer and the second encapsulation layer are the same.

15. The method of claim 12, wherein materials of at least two of the packaging layer, the first encapsulation layer and the second encapsulation layer are different.

16. The method of claim 12, wherein the at least one first circuit structure is a plurality of first circuit structures respectively disposed on opposing sides of the first encapsulation layer, and wherein the at least one second circuit structure is a plurality of second circuit structures respectively disposed on opposing sides of the second encapsulation layer.

17. The method of claim 16, wherein one of the plurality of first circuit structures has a plurality of first electrical contact pads, and the other one of the plurality of first circuit structures has a plurality of first conductive bumps, wherein one of the plurality of second circuit structures has a plurality of second conductive bumps, and the other one of the plurality of second circuit structures has a plurality of second electrical contact pads, wherein the second electronic module is disposed onto the plurality of first electrical contact pads of the first electronic module with the plurality of second conductive bumps via a solder material.

18. The method of claim 17, further comprising covering, by a bonding material, the plurality of second conductive bumps, the solder material and the first electrical contact pads.

19. The method of claim 17, further comprising covering, by a packaging material, the plurality of second conductive bumps, the solder material, the first electrical contact pads and the second electronic module.

20. The method of claim 17, further comprising firstly covering the plurality of second conductive bumps, the solder material and the first electrical contact pads via a bonding material, and then covering the bonding material and the second electronic module via a packaging material.

21. The method of claim 12, wherein the first circuit structure or the second circuit structure has a plurality of conductive bumps electrically connected to the routing structure.

22. The method of claim 12, wherein the first circuit structure or the second circuit structure has a plurality of electrical contact pads electrically connected to the routing structure.

23. The method of claim 12, further comprising forming another routing structure on the carrier, wherein the stacking component is disposed onto the another routing structure.

24. The method of claim 12, wherein the carrier and the plurality of conductive pillars are an integrally formed metal member.
